(19) United States
(12) Patent Application Publication
(10) Pub. No.: US 2008/0096367 A1
(43) Pub. Date: Apr. 24, 2008

(54) Method for Laser Dicing of a Substrate

(75) Inventors: Antonius Johannes Hendriks, Eindhoven (NL); Hendrik Jan Kettelarij, Eindhoven (NL); Ivar Jacco Boerefijn, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/576,546

(22) PCT Filed: Sep. 26, 2005
(86) PCT No.: PCT/IB05/53174

§ 371 Date: Apr. 3, 2007

(30) Foreign Application Priority Data
Oct. 5, 2004 (EP) 04104866.1

(51) Int. Cl. H01L 21/78; B23K 26/14

(52) U.S. Cl. 438/463; 219/121.67; 219/121.85; 257/E21.599

(57) ABSTRACT

The invention relates to a method for dicing a substrate with a laser apparatus, comprising the steps of delivering a laser beam (15) from said laser apparatus to said substrate to dice said substrate (1) in at least two dies. A first assist gas is supplied at the substrate during a first phase of said dicing method and a second assist gas is supplied at the substrate during a second subsequent phase of said dicing method. The method results in a reduced street-width for dicing of the substrate and consequently costly substrate area is saved. The invention also relates to a laser dicing system, a computer program product for executing the method and a silicon die obtainable by the method.

The invention relates to a method for dicing a substrate with a laser apparatus. The invention further relates to a laser dicing system and a computer program product comprising laser dicing strategy code portions. Moreover, the invention relates to a silicon die.

In the semiconductor industry, dies, such as silicon dies, are used in manufacturing chips. These dies are typically obtained in large quantities by mechanically sawing substrates or wafers of the appropriate material. In dicing these substrates, obviously some area of the substrate is lost as a consequence of dicing.

A trend has set to dice wafers by employing laser apparatus delivering a laser beam to the wafer instead of mechanical sawing. A drawback of this type of dicing is that the quality of the dicing edge of the substrate tends to be relatively poor. The street-width, being a measure of the total influenced zone of the substrate that is unsuitable for chip production, for certain products is e.g. 50 microns.

WO 03/090258 discloses the use of a program-controlled pulsed laser beam apparatus to dice a substrate. Gas handling equipment is employed to provide gas at the substrate prior to, during or after dicing. A passive inert gas, such as argon or helium, is provided to prevent oxidation of walls of a die during machining. Alternatively, an active gas, such as chlorofluoro-carbons and halocarbons, is provided to reduce the surface roughness of the die sidewalls and the amount of debris adhering to the sidewalls. In this way the quality of the sidewalls of the dies is improved.

A drawback of the prior art laser dicing method wherein passive inert gas is supplied at the substrate is the relatively large street-width. Consequently, costly area of the substrate is not available for chip production. Further, active gasses are not effective in laser separation of the substrate.

It is an object of the invention to provide a method and system for laser dicing of a substrate enabling reduction of the street-width.

This object is achieved by providing a method for dicing a substrate with a laser apparatus, comprising the steps of:

delivering a laser beam from said laser apparatus to said substrate to dice said substrate in at least two dies;

supplying a first assist gas at said substrate during a first phase of said dicing method, and

supplying a second assist gas at said substrate during a second subsequent phase of said dicing method.

This object is further achieved by providing a laser dicing system comprising a laser apparatus, a first container for a first assist gas, a second container for a second assist gas and a controller, wherein said laser apparatus is adapted to generate a laser beam for dicing said substrate and wherein said controller is adapted to supply said first assist gas in a first dicing phase and said second assist gas in a second subsequent dicing phase.

This object is moreover achieved by providing a computer program product loadable in a controller of a laser dicing system having a laser apparatus for dicing a substrate with a laser beam comprising laser dicing strategy code portions for:

delivering a laser beam from said laser apparatus to said substrate to dice said substrate in at least two dies;

supplying a first assist gas at said substrate during a first dicing phase, and

supplying a second assist gas at said substrate during a second subsequent dicing phase.

The sequential supply of the first assist gas and the second assist gas enables tailoring of the dicing process to the varying requirements for the atmospheric conditions during dicing to obtain a high quality die wall and accordingly a reduced street-width. Consequently, the usable substrate area increases and thus the number of dies or the size of each die of a substrate may increase. Preferably, the supply of the first assist gas is stopped before the second assist gas is supplied in order to optimally profit from the effect of each of the gasses.

The embodiment of the invention as defined in claims 3 and 8 provides the advantage of a high quality die sidewall and a reduced street-width. The effect of the non-oxidizing atmosphere, e.g. obtained by supplying a noble gas or nitrogen gas, is to maintain highly reflective sidewalls of the dicing lane to enhance dicing in the first phase of the dicing process. The effect of the subsequently supplied oxidizing atmosphere is to remove debris and droplets of the substrate material or to prevent formation of such debris and droplets. In the case of a silicon substrate, it was found that, in contrast to the case wherein only a nitrogen atmosphere was provided, silicon droplets were absent and accordingly crack formation, associated with the presence of these silicon droplets, was prevented or at least reduced.

The embodiment of the invention as defined in claim 4 has the advantage that nitrogen gas is relatively inexpensive and is typically available at the site of the laser apparatus since this gas is used for the laser apparatus itself as well.

The embodiment of the invention as defined in claims 5 and 9 has the advantage that the moment of switching from said first assist gas to said second assist gas can be based on a simple parameter. Most substrates in semiconductor industry are extremely standardized, such that the dicing effect of each run over the substrate is well known for a specific setting of the laser beam. It should however be appreciated that alternatively or in addition sensors can be provided to indicate the moment of switching from the first assist gas to the second assist gas.

It should be appreciated that the embodiments described above, or aspects thereof, may be combined.

The invention will be further illustrated with reference to the attached drawings, which schematically show a preferred embodiment according to the invention. It will be understood that the invention is not in any way restricted to this specific and preferred embodiment.

### IN THE DRAWINGS

FIG. 1 illustrates a substrate with a plurality of dicing lanes to obtain dies;

FIG. 2 is a schematic illustration of a laser dicing system according to an embodiment of the invention;

FIG. 3 is a schematic illustration of the laser head of the laser dicing system of FIG. 2;

FIG. 4 shows a timing diagram for a method according to an embodiment of the invention, and

FIGS. 5A-5D show results of laser dicing experiments in a nitrogen atmosphere and in a nitrogen atmosphere followed by an oxidizing atmosphere in top view and in cross section.

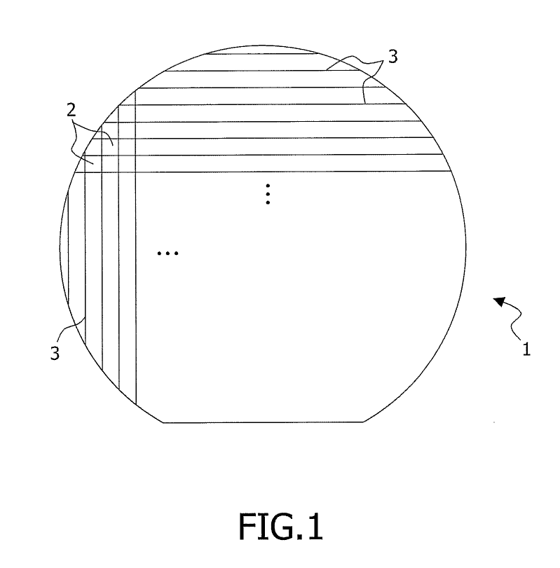

FIG. 1 depicts a substrate 1, preferably a silicon substrate, from which a large quantity of dies 2 is obtained by laser dicing. The dicing lanes 3 result from one or more dicing runs of a laser beam over the substrate 1. Conveniently, during dicing the substrate 1 is provided on a sticking tape (not shown) to maintain control over resulting parts or the individual dies 2 after separation. The dies 2 can subsequently be collected from the tape and employed for chip production.

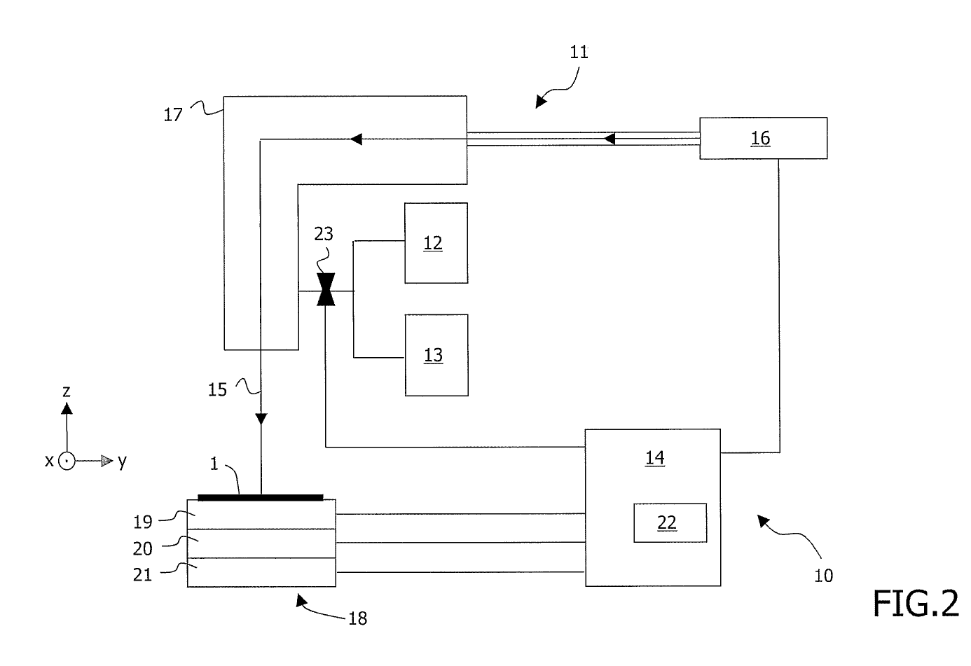

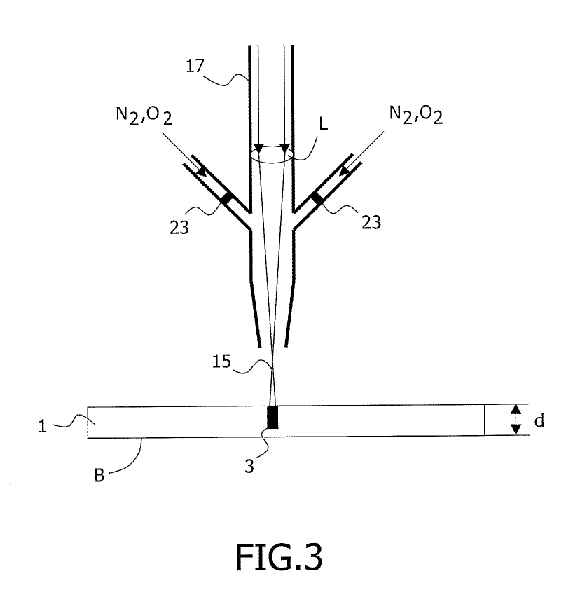

FIG. 2 schematically illustrates a laser dicing system 10 comprising a laser apparatus 11, a first container 12 for a first assist gas, a second container 13 for a second assist gas and a controller 14. FIG. 3 is a schematic illustration of the laser head of the laser dicing system 10 of FIG. 2.

The substrate 1 is a 215 μm thick silicon wafer. However, wafers having a different thickness d including 25 μm or 50 μm silicon wafers, can be used as well.

The laser apparatus 11 generates a laser beam 15 from a laser source 16 that is delivered via the beam delivery system 17 to the substrate 1 for inducing dice lanes 3. The laser apparatus 11 preferably is a pulsed (Q-switch) Nd:YAG laser with a pulse length between 50-500 nanoseconds at a frequency between 1-50 kHz, a peak intensity in the range of 0.5-2 GW/cm², a focus diameter in the range of 5-10 μm and a beam quality M²<1.3. The beam delivery system 17 comprises a plurality of components, such as mirrors, a wave plate, beam expanders, a focusing lens L (see FIG. 3) etc., generally known in the art. Other laser apparatus, such as a Nd:YVO (Vanadate)or Nd:YLF lasers in the wavelength range 1064 nm till 355 nm, may be used as well.

The substrate 1 is provided on a positioning table 18 comprising a rotational control module 19, a z-axis control module 20 and a x, y axis control module 21. Consequently, the laser apparatus 11 may retain its position while the dicing lanes 3 on the substrate are provided by moving the substrate 1 employing the various positioning modules 19, 20, 21 of the positioning table 18.

Further, the laser dicing system 10 comprises the controller 14, e.g. a computer device with a memory 22, a microprocessor and signal inputs and signal outputs, to control various components laser dicing system 10. As an example, the controller 14 controls the settings of the laser apparatus 11, such as the pulse length and the peak intensity. Further, the controller 14 controls the positioning of the substrate 1 by providing appropriate control signals for one or more of the various positioning modules 19, 20, 21 of the positioning table 18.

According to the invention, the laser dicing system 10 further comprises a switch or valve 23 to supply a first assist gas in a first phase of the dicing process from the first container 12 and a second assist gas in a second phase of the dicing process from the second container 13, wherein the second phase follows the first phase. The valve 23 can be controlled from the controller 14.

The first assist gas of the first container 12 is a gas able to provide a non-oxidizing atmosphere at the substrate 1, more particularly at the dicing lane 3, during a first phase of the laser dicing process. The non-oxidizing atmosphere may e.g. be obtained by supplying a noble gas, such as argon or helium, or nitrogen gas in sufficient quantities. Nitrogen gas may be preferred as this gas is conventionally also supplied within the beam delivery system 17 for flushing the optical components. The N₂ gas for flushing these optical components and for providing the non-oxidizing atmosphere may originate from the same container 12. However, preferably separate containers are used for the gas supply to allow specific design of the laser head to optimize the provision of the non-oxidizing atmosphere at the substrate 1.

The second assist gas of the second container 13 is a gas able to provide an oxidizing atmosphere at the substrate 1, more particularly at the dicing lane 3, during a second phase of the laser dicing process. The oxidizing atmosphere is preferably obtained by supplying gaseous oxygen or an oxygen containing gas.

FIG. 3 shows separate inlets 30, 31 for providing the first and second assist gas at the substrate 1. These separate inlets may result in a better controllable gas flow to the substrate 1. It should be appreciated that both inlets 30,31 may first be used to supply the first assist gas during the first phase of the laser dicing process and subsequently both inlets 30, 31 may be used to supply the second assist gas during a second phase of the laser dicing process. The gasses supplied via the inlets 30, 31 are fed by nozzles in the laser head to the substrate 1 substantially parallel to the laser beam 15. Alternatively or in addition, the first and/or the second assist gas is provided at the side of the substrate 1 or dicing lane 3.

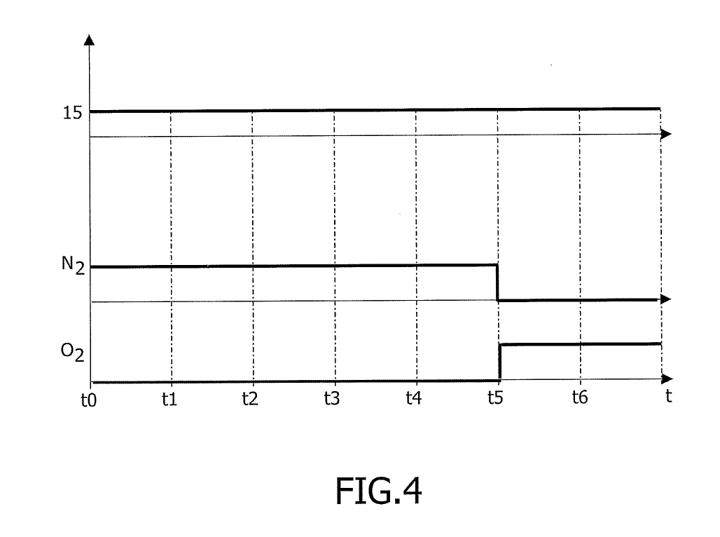

FIG. 4 shows a timing diagram for a method according to an embodiment of the invention employing the laser dicing system 10 of FIG. 2.

First a laser dicing strategy program is loaded in the memory 22 of the controller 14 for laser dicing of the substrate 1. The program contains information of the settings for the laser apparatus 11, the dicing runs to be made for dicing the substrate by moving the positioning table 18 and the moment of switching from supply of the first assist gas to the second assist gas.

The moment of switching from supplying the first assist gas to supplying the second assist gas can be determined in a number of ways. The laser dicing system 10 can be provided with one or more sensors (not shown) to detect a certain state of the substrate 1 during dicing. The controller 14 may be connected to these sensors and decide on the basis of predetermined criteria related to measurement results of these sensors when to supply the second assist gas. As an example, the sensors may monitor the dicing plasma.

As the substrates 1 for use in semiconductor industry are extremely well standardized, the use of sensors may not be required to determine the moment of switching from the first assist gas to the second assist gas. For a well designed laser dicing system 10, subsequent substrates 1 typically show very similar behavior.

Typically, the substrate 1 is not diced by a single dicing run, i.e. a single passing of the laser beam 15 over the substrate 1. The dicing lane 3 is usually formed in various passings, wherein the back side B (see FIG. 3) of the substrate 1 first does not show any separation trace. During subsequent dicing runs a separation pattern develops on the back side B. It has been found that when the separation pattern shows a track of holes, i.e. the adjacent dies 2 are still connected by various bridges of substrate material, the second assist gas can be provided advantageously. The occurrence of such a separation pattern is directly related to the number of dicing runs over the substrate. Accordingly, when the laser beam 15 exceeds this predetermined number of dicing runs for a given substrate 1 and given laser settings, the second assist gas may be provided.

In FIG. 4 the laser beam 15 is delivered at t=t0. The first dicing run is from t0 to t1. It is assumed that the first phase of the dicing process requires five dicing runs and consequently takes the time interval t0-t5 before the separation pattern described in the previous paragraph appears. During this first phase, the valve 23 is controlled by the laser dicing strategy program of the controller 14 such that the first assist gas is provided at the substrate 1 from the first container 12. Consequently, the sidewalls of the dicing lane 3 remain reflective as oxidation of these walls is prevented, thereby enabling efficient use of the laser energy for dicing the substrate 1.

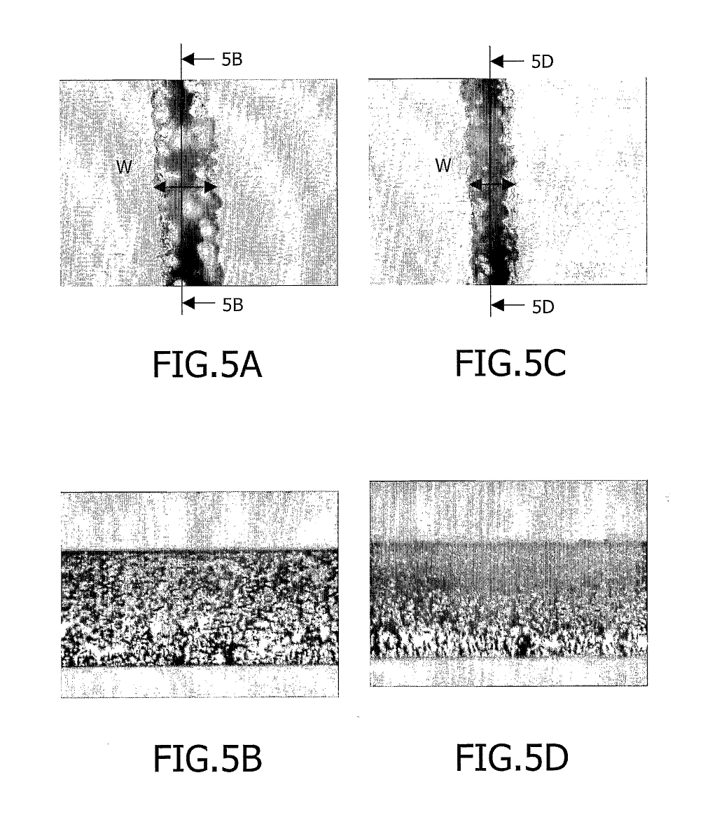

At the moment t5, the predetermined number of dicing runs has been reached and the second phase of the dicing process is initiated. The controller 14 generates a control signal for the valve 23 to supply the oxygen gas at the substrate 1 to provide the oxidizing atmosphere. Consequently debris and silicon droplets are burnt and a reduced street-width W is obtained (see FIG. 5C). After seven dicing runs, the substrate 1 is diced along the dicing lane 3.

It is noted that various modifications of the timing diagram of FIG. 4 can be envisaged without departing from the scope of the present invention. For instance, the first assist gas is not necessarily supplied immediately during the first dicing run. Moreover, in reality there will be no instantaneous switch from the first assist gas to the second assist gas, as there are typically delays in the system resulting e.g. from the length of the assist gas supply tubes. Further, the supply of the second assist gas not necessarily stops simultaneously with the last dicing run.

Finally, FIGS. 5A-5D show results of laser dicing experiments in top view (FIGS. 5A and 5C) and cross-section (FIGS. 5B and 5D).

FIGS. 5A and 5B show photographs of a laser diced silicon substrate wherein dicing was performed in the presence of nitrogen gas.

FIGS. 5C and 5D show photographs of a laser diced silicon substrate wherein dicing was performed in the presence of nitrogen gas followed by oxygen gas according to the invention. Clearly, the street-width W has reduced considerably and amounts to less than 20 μm. Further, the die sidewall of the silicon die is substantially free from cracks and silicon droplets

It should be acknowledged that the present invention is not limited to the above-described embodiment.

1. A method for dicing a substrate (1) with a laser apparatus (11), comprising the steps of:
delivering a laser beam (15) from said laser apparatus to said substrate to dice said substrate in at least two dies (2);
supplying a first assist gas at said substrate during a first phase (t0-t5) of said dicing method, and
supplying a second assist gas at said substrate during a second subsequent phase (t5-t7) of said dicing method.

2. The method according to claim 1, wherein said second assist gas is supplied substantially after stopping supply of said first assist gas.

3. The method of claim 1, wherein said first assist gas provides a non-oxidizing atmosphere at said substrate and said second gas provides an oxidizing atmosphere at said substrate.

4. The method of claim 3, wherein said first assist gas contains nitrogen gas.

5. The method of claim 1, wherein said first phase comprises a predetermined number of dicing runs of said laser beam (15) over said substrate (1) and said second assist gas is supplied after said predetermined number of dicing runs.

6. The method of claim 1, wherein said substrate (1) is a silicon wafer.

7. A laser dicing system (10) comprising a laser apparatus (11), a first container (12) for a first assist gas, a second container (13) for a second assist gas and a controller (14), wherein said laser apparatus is adapted to generate a laser beam (15) for dicing said substrate and wherein said controller (14) is adapted to supply said first assist gas during a first dicing phase and said second assist gas during a second subsequent dicing phase.

8. The laser dicing system (10) of claim 7, wherein said first assist gas is adapted to provide a non-oxidizing atmosphere at said substrate and said second assist gas is adapted to provide an oxidizing atmosphere at said substrate.

9. The laser dicing system (10) of claim 7, wherein said first phase has a predetermined number of dicing runs of said laser beam (15) over said substrate (1) and said controller (14) is programmed to count the number of dicing runs and to enable supply of said second assist gas after said number of dicing runs exceeds said predetermined number of dicing runs.

10. A computer program product loadable in a controller (14) of a laser dicing system (10) having a laser apparatus (11) for dicing a substrate (1) with a laser beam (15) comprising laser dicing strategy code portions for:
delivering a laser beam from said laser apparatus to said substrate to dice said substrate in at least two dies;
supplying a first assist gas at said substrate during a first dicing phase, and
supplying a second assist gas at said substrate during a second subsequent dicing phase.

11. A silicon die (2) obtainable by the method of claim 1.

12. A silicon die (2) having a dicing sidewall free or substantially free of cracks and droplets of silicon.
